(19) United States
(12) Patent Application Publication
(10) Pub. No.: US 2016/0380009 A1
(43) Pub. Date: Dec. 29, 2016

(54) THIN FILM TRANSISTOR ARRAY SUBSTRATE AND MANUFACTURING METHOD THEREOF

(71) Applicant: Shenzhen China Star Optoelectronics Technology Co. Ltd., Shenzhen (CN)

(72) Inventor: Zhuming DENG, Shenzhen (CN)

(73) Assignee: Shenzhen China Star Optoelectronics Technology Co. Ltd, Shenzhen (CN)

(21) Appl. No.: 14/767,683

(22) PCT Filed: Jun. 25, 2015
(86) PCT No.: PCT/CN2015/082300

§ 371 Date: Aug. 13, 2015

(30) Foreign Application Priority Data
Jun. 24, 2015 (CN) 201510351452.9

(51) Int. Cl. H01L 27/12

(52) U.S. Cl. CPC H01L 27/1288; H01L 27/124; H01L 27/1222

(57) ABSTRACT

A thin film transistor (TFT) array substrate and its manufacturing method are disclosed. The TFT array substrate includes a component assembly layer, a passivation layer and a pixel electrode layer. The passivation layer is disposed on the component assembly layer, and a hole and a first recess are provided on the passivation layer. The pixel electrode layer is disposed on the passivation layer and inside the first recess, and the pixel electrode layer is connected with the second signal line layer by the hole. The present invention can reduce the manufacturing cost and improve the manufacturing efficiency.

### FIELD OF THE INVENTION

The present invention relates to display technology, and more particularly to a thin film transistor (TFT) array substrate and manufacturing method thereof.

### BACKGROUND OF THE INVENTION

The conventional manufacturing process of a TFT array substrate generally requires providing a through hole and recesses on its passivation layer, and a pixel electrode layer is disposed on the surface of the passivation layer and inside the recesses. Additionally, the pixel electrode layer is connected with the data line layer of the TFT array substrate by passing through the through hole.

In the conventional technical solution described above, the through-hole and the recesses disposed on the passivation layer are implemented separately, that is, the through-hole and the recesses disposed on the passivation layer are two separate steps.

In response to the foregoing two separate steps, two separate Normal Mask (ordinary mask) processes are required. Consequently, the foregoing technical solution cost more, and the manufacturing efficiency of the TFT array substrate is not good.

Therefore, it is necessary to propose a new technical solution to solve the technical problems.

### SUMMARY OF THE INVENTION

It is an object of the present invention to provide a TFT array substrate and its manufacturing method which can reduce the manufacturing cost of the TFT array substrate and improve the manufacturing efficiency of the TFT array substrate.

To solve the foregoing problem, as embodied, a technical solution of the present invention is as follows:

According to one embodiment of the present invention, a TFT array substrate comprises:

a component assembly layer comprises:

a substrate;

a first signal line layer;

a semiconductor layer; and

a second signal line layer;

a passivation layer, disposed on the component assembly layer, having a hole and an array of recesses provided thereon, the array of recesses including at least a first recess; and

a pixel electrode layer, disposed on the passivation layer and inside the array of recesses, and connected with the second signal line layer by the hole;

wherein the hole has a first depth, and the first recess has a second depth;

wherein the array of recesses and the hole are both formed in a first mask process;

wherein the array of recesses further includes at least a third recess; and

wherein any two among the hole, the first recess, and the third recess are formed in a second mask process, and the remaining among the hole, the first recess, and the third recess is formed in a third mask process.

In the above TFT array substrate, the mask corresponding to the first mask process comprises:

a first region, having a first aperture ratio which corresponds to the first depth; and
at least a second region, having a second aperture ratio which corresponds to the second depth;
wherein the array of recesses further includes at least a second recess which has a third depth; and
the mask corresponding to the first mask process further includes:
   a third region, having a third aperture ratio which corresponds to the third depth.

According to another embodiment of the present invention, a TFT array substrate comprises:

a component assembly layer comprises:
a substrate;
a first signal line layer;
a semiconductor layer; and
a second signal line layer;

a passivation layer, disposed on the component assembly layer, having a hole and an array of recesses provided thereon, the array of recesses including at least a first recess; and

a pixel electrode layer, disposed on the passivation layer and inside the array of recesses, and connected with the second signal line layer by the hole.

In the above TFT array substrate, the hole has a first depth and the first recess has a second depth, and the array of recesses and the hole are both formed in a first mask process.

In the above TFT array substrate, a mask corresponding to the first mask process comprises:

a first region, having a first aperture ratio which corresponds to the first depth; and

at least one second region, having a second aperture ratio which corresponds to the second depth.

In the above TFT array substrate, the first depth and the second depth are simultaneously formed by using the first mask to perform the first mask process to the passivation layer, and the first mask has the first region and the second region.

In the above TFT array substrate, the first aperture ratio is equal to 100%, and the second aperture ratio is greater than 0% and less than 100%.

In the above TFT array substrate, the array of recesses further includes at least one second recess which has a third depth;

the mask corresponding to the first mask process further includes:

at least one third region, having a third aperture ratio which corresponds to the third depth.

In the above TFT array substrate, the first depth, the second depth, and the third depth are simultaneously formed by using the first mask to perform the first mask process on the passivation layer, and the first mask has the first region, the second region and the third region.

In the above TFT array substrate, the first aperture ratio is equal to 100%, and the second aperture ratio and the third aperture ratio are greater than 0% and less than 100%.

In the above TFT array substrate, the array of recesses further includes at least one third recess, and any two among the hole, the first recess, and the third recess are formed in a second mask process, and the remaining among the hole, the first recess, and the third recess is formed in a third mask process.

According to yet another embodiment of the present invention, a method for manufacturing a TFT array substrate is provided, the method comprising the following steps of:

A: forming a component assembly layer, wherein the component assembly layer comprises a substrate, a first signal line layer, a semiconductor layer and a second signal line layer;

B: disposing a passivation layer on the component assembly layer;

C: performing a mask process on a passivation layer to form a hole and an array of recesses on the passivation layer, wherein the array of recesses comprises at least a first recess; and

D: disposing a pixel electrode layer on a surface of the passivation layer and inside the array of recesses, wherein the pixel electrode layer is connected to a second signal line layer by the hole.

In the above method for manufacturing a TFT array substrate, the hole has a first depth and the first recess has a second depth, and the step C comprises the following step of:

c1: forming the array of recesses and the hole in the first mask process.

In the above method for manufacturing a TFT array substrate, a mask corresponding to the first mask process comprises:

a first region, having a first aperture ratio which corresponds to the first depth; and

at least one second region, having a second aperture ratio which corresponds to the second depth.

In the above method for manufacturing a TFT array substrate, the step cl comprises the following step of:

c11: performing a first mask process on the passivation layer to simultaneously form the first depth and the second depth by using the first mask that has the first region and the second region.

In the above method for manufacturing a TFT array substrate, the first aperture ratio is equal to 100%, and the second aperture ratio is greater than 0% and less than 100%.

In the above method for manufacturing a TFT array substrate, the array of recesses further includes at least one second recess which has a third depth;

the mask corresponding to the first mask process further includes:

at least one third region, having a third aperture ratio which corresponds to the third depth.

In the above method for manufacturing a TFT array substrate, the step c1 comprises the following step of:

c12: performing a first mask process on the passivation layer to simultaneously form the first depth, the second depth, and the third depth by using the first mask that has the first region, the second region and the third region.

In the above method for manufacturing a TFT array substrate, the first aperture ratio is equal to 100%, and the second aperture ratio and the third aperture ratio are greater than 0% and less than 100%.

In the above method for manufacturing a TFT array substrate, the array of recesses further includes at least one third recess, and the step C comprises the following step of:

c2: forming any two among the hole, the first recess, and the third recess in a second mask process, and

c3: forming the other one among the hole, the first recess, and the third recess in a third mask process.

In comparison with the prior art, the present invention can save one mask process so that it is helpful in reducing the manufacturing cost of the TFT array substrate and improving the manufacturing efficiency of the TFT array substrate.

To allow the foregoing summary of the present invention to be more clearly understood, there are preferred embodiments, which proceed with reference to the accompanying drawings, and are described in detail as follows.

### BRIEF DESCRIPTION OF THE DRAWINGS

FIG. 1 to FIG. 4 are schematic views that illustrate a TFT array substrate produced by a manufacturing method according to a first embodiment of the present invention.

FIG. 5 is a schematic view that illustrates a mask used during the manufacturing process of the TFT array substrate shown in FIG. 1 to FIG. 4.

FIG. 6 is a schematic view that illustrates a TFT array substrate produced by a manufacturing method according to a second embodiment of the present invention.

FIG. 7 is a schematic view that illustrates a mask used during the manufacturing process of the TFT array substrate shown in FIG. 6.

FIG. 8 is a flow chart that illustrates a manufacturing method according to a first embodiment of the present invention.

FIG. 9 is a flow chart that illustrates a manufacturing method according to a third embodiment of the present invention.

### DETAILED DESCRIPTION OF THE INVENTION

Regarding the terms used in this specification, “one embodiment” or “an embodiment” means that the description in connection with the embodiment serves as an example, instance, or illustration of the disclosure. Furthermore, the articles “a” and “an” as used in this specification and the appended claims should generally be construed to mean “one or multiple”, unless specified or clear from context to be directed towards a singular form.

Refer to FIG. 4, which shows a schematic view of a TFT array substrate produced by a manufacturing method according to a first embodiment of the present invention.

The TFT array substrate of this embodiment includes a component assembly layer 101, a passivation layer 201, and a pixel electrode layer 401. The component assembly layer 101 includes a substrate 1011, a first signal line layer 1012, a semiconductor layer 1014, and a second signal line layer 1017. The component assembly layer 101 further includes a first insulating layer 1013, a second insulating layer 1015, and the drain wiring layer 1016.

The first signal line layer 1012 may be a scan line layer. The semiconductor layer 1014 may be an amorphous silicon layer or a polycrystalline silicon layer. The second signal line layer 1017 may be a data line layer. The scan line layer is disposed below the semiconductor layer 1014 (the semiconductor layer 1014 is the amorphous silicon layer), and the first insulating layer 1013 is disposed between the scan line layer and the amorphous silicon layer. The second insulating layer 1015 is disposed above the amorphous silicon layer. The data line layer is disposed above the second insulating layer 1015, and the data line may be connected to the amorphous silicon layer by passing through the second insulating layer 1015. Alternatively, the scan line layer is disposed above the semiconductor layer 1014 (the semiconductor layer 1014 is the polycrystalline silicon layer), and the first insulating layer 1013 is disposed between the scan line layer and the amorphous silicon layer. The second insulating layer 1015 is disposed above the scan line. The data line layer is disposed above the second insulating layer 1015, and the data line may be connected to the polycrystalline silicon layer by passing through the first insulating layer 1013.

The passivation layer 201 is disposed on the component assembly layer 101, and a hole 302 and an array of recesses 301 are provided on the passivation layer 201. The array of recesses 301 includes at least one first recess 3011.

The pixel electrode layer 401 is disposed on the passivation layer 201 and inside the array of recess 301, and the pixel electrode layer 401 is connected with the second signal line layer 1017 by the hole 302.

In this embodiment, the hole 302 has a first depth H1, and the first recess 3011 has a second depth H2.

The array of recesses 301, e.g. the first recess 3011, and the hole 302 are formed in the first mask process. That is, the array of recess 301 and the hole 302 are both formed in the same mask process, e.g. Gray Tone Mask (GTM).

Compared with the conventional technical solution, the aforementioned technical solution can save a mask process, e.g. a Normal Mask, and it is helpful in reducing the manufacturing cost of the TFT array substrate. Furthermore, the efficiency of manufacturing the TFT array substrate can be improved.

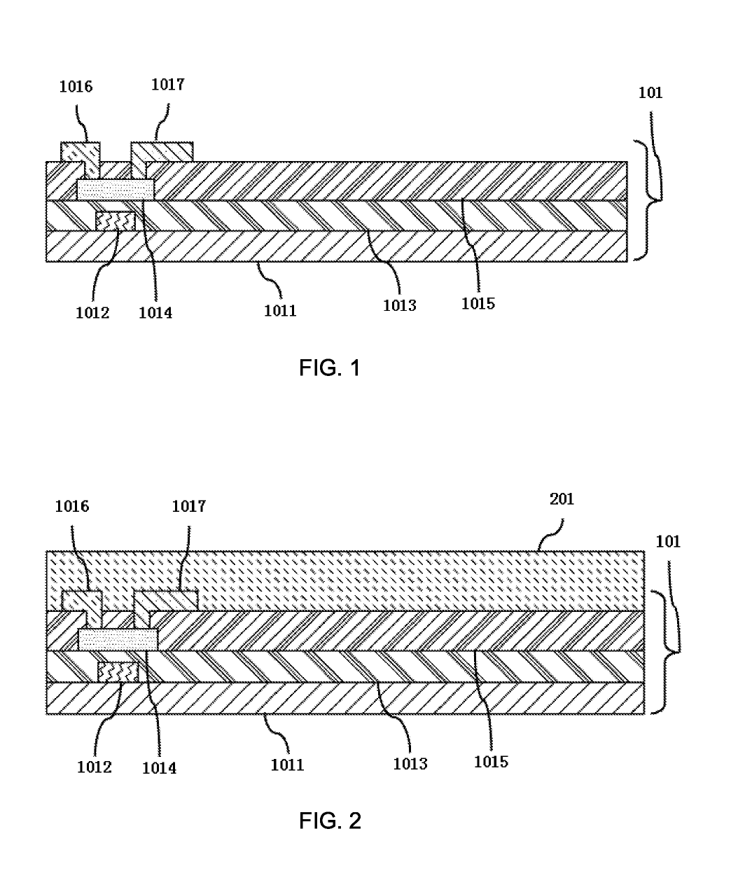

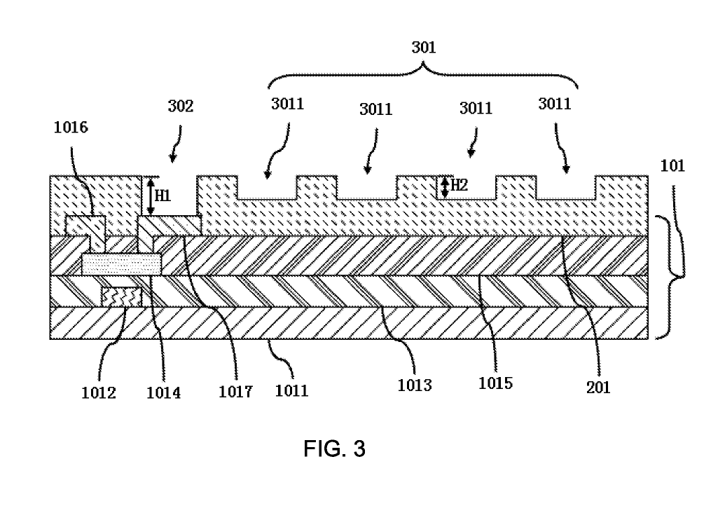

Refer to FIG. 5, which shows a schematic view of a mask used during the manufacturing process of the TFT array substrate shown in FIG. 1-FIG. 4.

In this embodiment, the mask (first mask 501) corresponding to the first mask process includes a first region 5011 and at least one second region 5012. The first region 5011 has a first aperture ratio, which corresponds to the first depth H1. The second region 5012 has a second aperture ratio, which corresponds to the second depth H2. The depth of the first recess 3011 (the second depth H2) can be set according to aperture ratio of GTM (aperture ratio 0-100%).

In other words, the first depth H1 and the second depth H2 in the passivation layer 201 are formed in such a manner:

The first mask process is performed on the passivation layer 201 by using the first mask 501 having the first region 5011 and the second region 5012 to simultaneously form the first depth H1 and the second depth H2, in which the first region 5011 has the first aperture ratio and the second region 5012 has the second aperture ratio. For example, the first aperture ratio is 100% and the second aperture ratio is a%, which is within the range of 0-100%, e.g., the a% is 66.7% or 60%.

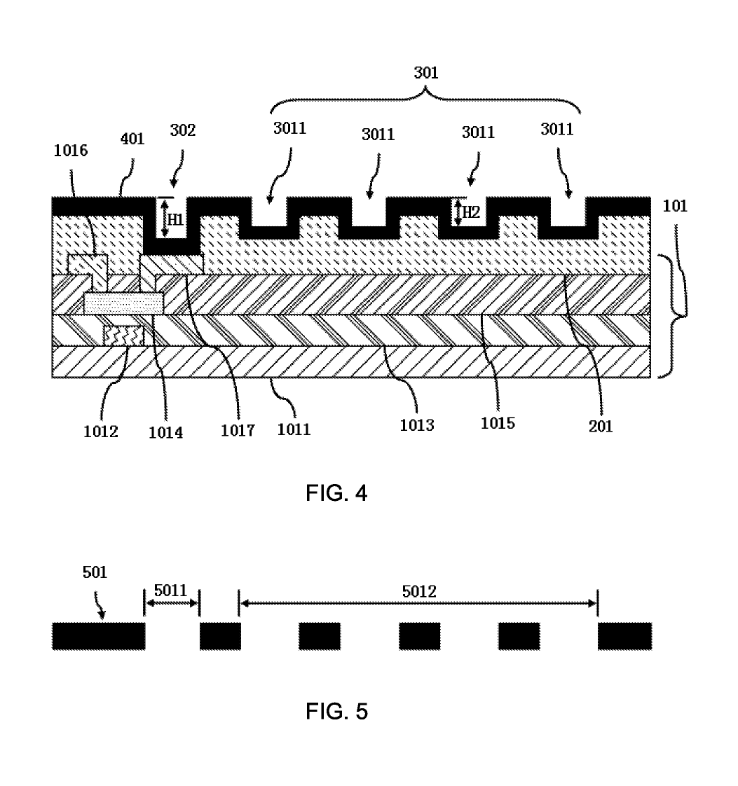

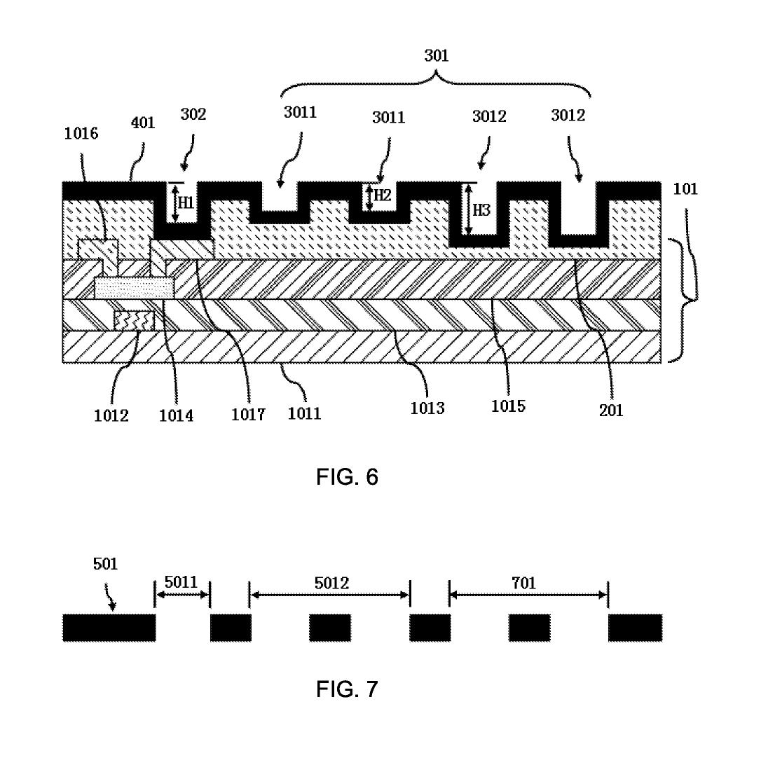

With reference to FIG. 6 and FIG. 7, a schematic view of a TFT array substrate according to a second embodiment of the present invention is shown in FIG. 6. FIG. 7 shows a schematic view of a mask used during the manufacturing process of the TFT array substrate shown in FIG. 6. The second embodiment is similar to the first embodiment, the distinction between them is that:

In the second embodiment, the recesses in the array of recesses 301 have two different depths. Namely, the array of recesses 301 further includes at least one second recess 3012, and the second recess 3012 has a third depth H2.

To form the first depth H1, the second depth H2, and the third depth H2 in the same mask process (the first mask process), the mask (first mask 501) corresponding to the first mask process further includes a third region 701. The third region 701 has a third aperture ratio, which corresponds to the third depth H2.

The depth of the second recess 3012 (the third depth H2) can be set according to aperture ratio of GTM (aperture ratio 0-100%).

In other words, the first depth H1, the second depth H2, and the third depth H2 in the passivation layer 201 are formed in such a manner:

The first mask process is performed on the passivation layer 201 by using the first mask 501 having the first region 5011, the second region 5012, and the third region 701 to simultaneously form the first depth H1, the second depth H2 and the third depth H2 where the first region 5011 has the first aperture ratio, the second region 5012 has the second aperture ratio, and the third region 701 has the third aperture ratio. For example, the first aperture ratio is 100%, the second aperture ratio is (a%), and the third aperture ratio is (b%) which are both within the range of 0-100%, but a is not equal to b, e.g., the a% and the b% being respectively one of either 66.7% or 60%.

The TFT array substrate according to a third embodiment of the present is similar to the first embodiment, the distinction between them is that:

In the third embodiment, the recesses in the array of recesses 301 have two different depths. Namely, the array of recesses 301 further includes at least one third recess 3012 which has a fourth depth.

Any two among the hole 302, the first recess 3011, and the third recess are formed in a second mask process, and the remaining among the hole 302, the first recess 3011, and the third recess is formed in a third mask process.

The second mask process corresponds to a Gray Tone Mask (GTM), and the third mask process corresponds to a mask which is different from GTM, for example, a Normal Mask.

In any one of the first to the third embodiments, the pixel electrode layer 401 includes at least two of a first portion and at least two of a second portion.

The first portion of the pixel electrode layer covers the surface of the passivation layer 201. The second portion of the pixel electrode layer includes one which is bent toward and extended to the inner surface of the recess from the surface of the passivation layer 201 towards the recess in the array of recesses 301 (the first recess 3011, the second recess 3012, or the third recess), and the other of which is the inner surface of the recess is bended toward and extended to the surface of the passivation layer 201. The first portion is connected to the second portion.

In other words, the passivation layer 201 201 is not disposed on a plane, and its surface is rugged. The whole surface of the passivation layer 201 is attached on the rugged surface of the passivation layer 201, namely, the pixel electrode layer 401 is entirely attached to the surface of the passivation layer 201 and the inner surface of the recess (the first recess 3011, the second recess 3012, or the third recess). The method is instrumental to allow a display panel made from the TFT array substrate to have a higher display performance (e.g., having a high transmittance).

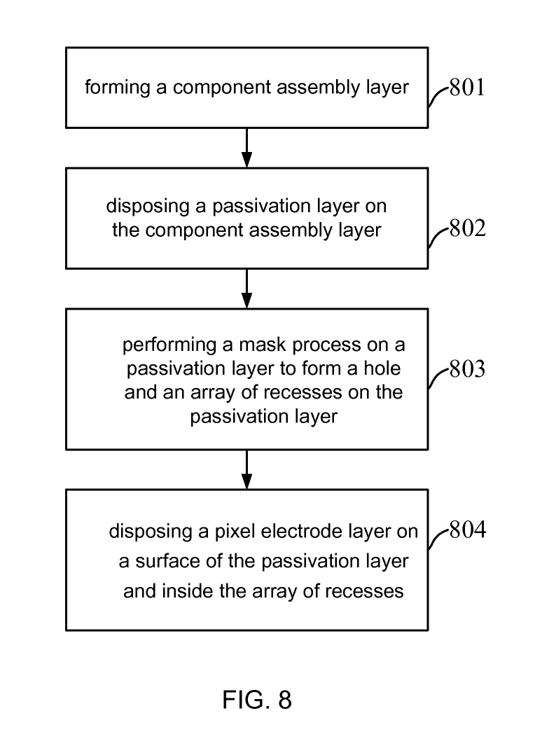

Refer to FIGS. 1 to 4 and FIG. 8, which show a schematic view of a TFT array substrate produced by a manufacturing method according to a first embodiment of the present invention. FIG. 8 is a flow chart that illustrates a manufacturing method for a TFT array substrate according to a first embodiment of the present invention.

A method for manufacturing a TFT array substrate according to a first embodiment of the present invention includes the following steps:

A (step 801): forming a component assembly layer 101, in which the component assembly layer 101 comprises a substrate 1011, a first signal line layer 1012, a semiconductor layer 1014, and a second signal line layer 1017.

B (step 802): disposing a passivation layer 201 on the component assembly layer 101.

C (step 803): performing a mask process on a passivation layer 201 to form a hole 302 and an array of recesses 301 on the passivation layer, wherein the array of recesses 301 comprises at least a first recess 3011.

D (step 804): disposing a pixel electrode layer 401 on a surface of the passivation layer 201 and inside the array of recesses 301, wherein the pixel electrode layer 401 is connected to a second signal line layer 1017 by the hole 302.

In this embodiment, the hole 302 has a first depth H1, and the first recess 3011 has a second depth H2.

The step C (step 803) includes the following step of:

c1: forming the array of recesses 301 (the first recess 3011) and the hole 302 in the first mask process. That is, the array of recesses 301 (the first recess 3011) and the hole 302 are formed in the same mask process (Gray Tone Mask).

In this embodiment, the mask (first mask 501) corresponding to the first mask process includes a first region 5011 and at least one second region 5012. The first region 5011 has a first aperture ratio, which corresponds to the first depth H1. The second region 5012 has a second aperture ratio, which corresponds to the second depth H2. The depth of the first recess 3011 (the second depth H2) can be set according to aperture ratio of GTM (aperture ratio 0-100%).

In other words, the first depth H1 and the second depth H2 in the passivation layer 201 are formed in such a manner:

The first mask process is performed on the passivation layer 201 by using the first mask 501 having the first region 5011 and the second region 5012 to simultaneously form the first depth H1 and the second depth H2, in which the first region 5011 has the first aperture ratio and the second region 5012 has the second aperture ratio. For example, the first aperture ratio is 100% and the second aperture ratio is a%, which is within the range of 0-100%, e.g., the a% is 66.7% or 60%.

Compared with the conventional technical solution, the aforementioned technical solution can save a mask process, e.g. a Normal Mask, and it reduces the manufacturing cost of the TFT array substrate. Furthermore, the efficiency of manufacturing the TFT array substrate can be improved.

A method for manufacturing a TFT array substrate according to a second embodiment of the present invention is similar to the first embodiment, the distinction between them is that:

In the second embodiment, the recesses in the array of recesses 301 have two different depths. Namely, the array of recesses 301 further includes at least one second recess 3012, and the second recess 3012 has a third depth H2.

To form the first depth H1, the second depth H2, and the third depth H2 in the same mask process (the first mask process), the mask (first mask 501) corresponding to the first mask process further includes a third region 701. The third region 701 has a third aperture ratio which corresponds to the third depth H2.

The depth of the second recess 3012 (the third depth H2) can be set according to aperture ratio of GTM (aperture ratio 0-100%).

In other words, the first depth H1, the second depth H2, and the third depth H3 in the passivation layer 201 are formed in such a manner:

The first mask process is performed on the passivation layer 201 by using the first mask 501 having the first region 5011, the second region 5012, and the third region 701 to simultaneously form the first depth H1, the second depth H2, and the third depth H3 where the first region 5011 has the first aperture ratio, the second region 5012 has the second aperture ratio, and the third region 701 has the third aperture ratio. For example, the first aperture ratio is 100%, the second aperture ratio is a%, and the third aperture ratio is b% which are both within the range of 0-100%, but a is not equal to b, e.g., the a% and the b% being respectively one of either 66.7% or 60%.

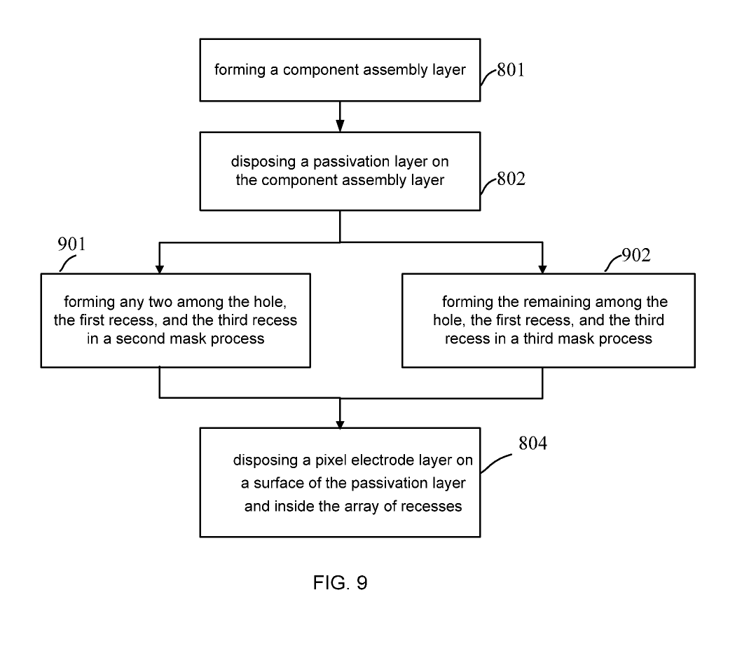

Refer to FIG. 9, which shows a flow chart of a manufacturing method for a TFT according to a third embodiment of the present invention. This embodiment is similar to the first embodiment described above, the distinction between them is that:

In this embodiment, the recesses in the array of recesses 301 have two different depths. Namely, the array of recesses 301 further includes at least one third recess 3012 which has a fourth depth.

The step C (step 803) includes the steps of:

c2 (step 901): forming any two among the hole 302, the first recess 3011, and the third recess in a second mask process.

c3 (step 902): forming the remaining among the hole 302, the first recess 3011, and the third recess in a third mask process.

The second mask process corresponds to a Gray Tone Mask (GTM), and the third mask process corresponds to a mask which is different from GTM, for example, a Normal Mask.

Despite one or more preferred embodiments of the present invention having been illustrated and described, those having ordinary skills in the art may easily contemplate equivalent changes and modifications according to the disclosure and drawings of the present invention. All such modifications and variations are considered to be encompassed in the scope defined by the claims of the present invention. Particularly with regard to the various functions performed by the above-described components, the terms used to describe such components are intended to perform the specified function corresponding to the component, which may be performed by any other components (functionally equivalent unless otherwise indicated), even though other components are not the same in the structure as those shown in the exemplary implementations of this specification. Furthermore, although a particular feature relating to a number of embodiments has been disclosed in this specification, this feature may be combined with one or more other features to have other embodiments which are desirable and advantageous to a given or particular application. Moreover, the terms “including”, “having”, “containing”, or variations thereof are used in the detailed description or the claims with a meaning similar to the term “comprising”.

In summary, while the present invention has been described with the aforementioned preferred embodiments, it is preferable that the descriptions relating to the above embodiments should be construed as exemplary rather than as limiting of the present invention. One of ordinary skill in the art can make a variety of modifications and variations without departing from the spirit and scope of the present invention as defined by the following claims.

What is claimed is:

1. A TFT array substrate comprising:
a component assembly layer comprises:
a substrate;
a first signal line layer;
a semiconductor layer; and
a second signal line layer;
a passivation layer, disposed on the component assembly layer, having a hole and an array of recesses provided thereon, the array of recesses including at least a first recess; and
a pixel electrode layer, disposed on the passivation layer and inside the array of recesses, and connected with the second signal line layer by the hole;
wherein the hole has a first depth, and the first recess has a second depth;
wherein the array of recesses and the hole are both formed in a first mask process;
wherein the array of recesses further includes at least a third recess; and
wherein any two among the hole, the first recess, and the third recess are formed in a second mask process, and the remaining among the hole, the first recess, and the third recess is formed in a third mask process.

2. The TFT array substrate according to claim 1, wherein a mask corresponding to the first mask process comprises:
a first region, having a first aperture ratio which corresponds to the first depth; and
at least a second region, having a second aperture ratio which corresponds to the second depth;
wherein the array of recesses further includes at least a second recess which has a third depth; and
the mask corresponding to the first mask process further includes:
a third region, having a third aperture ratio which corresponds to the third depth.

3. A TFT array substrate comprising:
a component assembly layer comprises:
a substrate;
a first signal line layer;
a semiconductor layer; and
a second signal line layer;
a passivation layer, disposed on the component assembly layer, having a hole and an array of recesses provided thereon, the array of recesses including at least a first recess; and
a pixel electrode layer, disposed on the passivation layer and inside the array of recesses, and connected with the second signal line layer by the hole.

4. The TFT array substrate according to claim 3, wherein the hole has a first depth and the first recess has a second depth, the array of recesses and the hole are both formed in a first mask process.

5. The TFT array substrate according to claim 4, wherein a mask corresponding to the first mask process comprises:
a first region, having a first aperture ratio which corresponds to the first depth; and
at least one second region, having a second aperture ratio which corresponds to the second depth.

6. The TFT array substrate according to claim 5, wherein the first depth and the second depth are simultaneously formed by using the first mask to perform the first mask process to the passivation layer, and the first mask has the first region and the second region.

7. The TFT array substrate according to claim 5, wherein the first aperture ratio is equal to 100%, and the second aperture ratio is greater than 0% and less than 100%.

8. The TFT array substrate according to claim 5, wherein the array of recesses further includes at least one second recess which has a third depth;
the mask corresponding to the first mask process further includes:
at least one third region, having a third aperture ratio which corresponds to the third depth.

9. The TFT array substrate according to claim 8, wherein the first depth, the second depth, and the third depth are simultaneously formed by using the first mask to perform the first mask process on the passivation layer, and the first mask having the first region, the second region and the third region.

10. The TFT array substrate according to claim 8, wherein the first aperture ratio is equal to 100%, and the second aperture ratio and the third aperture ratio are greater than 0% and less than 100%.

11. The TFT array substrate according to claim 3, wherein the array of recesses further includes at least one third recess, and any two among the hole, the first recess, and the third recess are formed in a second mask process, and the remaining among the hole, the first recess, and the third recess is formed in a third mask process.

12. A method for manufacturing a TFT array substrate, the method comprising the following steps of:
A: forming a component assembly layer, wherein the component assembly layer comprises a substrate, a first signal line layer, a semiconductor layer and a second signal line layer;
B: disposing a passivation layer on the component assembly layer;
C: performing a mask process on a passivation layer to form a hole and an array of recesses on the passivation layer, wherein the array of recesses comprises at least a first recess; and
D: disposing a pixel electrode layer on a surface of the passivation layer and inside the array of recesses, wherein the pixel electrode layer is connected to a second signal line layer by the hole.

13. The method for manufacturing a TFT array substrate according to claim 12, wherein the hole has a first depth and the first recess has a second depth, and the step C comprises the following step of:
c1: forming the array of recesses and the hole in the first mask process.

14. The method for manufacturing a TFT array substrate according to claim 13, a mask corresponding to the first mask process comprises:
a first region, having a first aperture ratio which corresponds to the first depth; and
at least one second region, having a second aperture ratio which corresponds to the second depth.

15. The method for manufacturing a TFT array substrate according to claim 14, wherein the step c1 comprises the following step of:
c11: performing a first mask process on the passivation layer to simultaneously form the first depth and the second depth by using the first mask that has the first region and the second region.

16. The method for manufacturing a TFT array substrate according to claim 14, wherein the first aperture ratio is equal to 100%, and the second aperture ratio is greater than 0% and less than 100%.

17. The method for manufacturing a TFT array substrate according to claim 14, wherein the array of recesses further includes at least one second recess which has a third depth;
the mask corresponding to the first mask process further includes:
at least one third region, having a third aperture ratio which corresponds to the third depth.

18. The method for manufacturing a TFT array substrate according to claim 17, wherein the step c1 comprises the following step of:
c12: performing a first mask process on the passivation layer to simultaneously form the first depth, the second depth, and the third depth by using the first mask that has the first region, the second region and the third region.

19. The method for manufacturing a TFT array substrate according to claim 17, wherein the first aperture ratio is equal to 100%, and the second aperture ratio and the third aperture ratio are greater than 0% and less than 100%.

20. The method for manufacturing a TFT array substrate according to claim 12, wherein the array of recesses further includes at least one third recess, and the step C comprises the following step of:
c2: forming any two among the hole, the first recess, and the third recess in a second mask process, and
c3: forming the other one among the hole, the first recess, and the third recess in a third mask process.
